(19) United States
(12) Patent Application Publication
(10) Pub. No.: US 2026/0369321 A1
(43) Pub. Date: Nov. 19, 2026

(54) NON-VOLATILE MEMORY

(71) Applicant: MACRONIX International Co., Ltd., Hsinchu (TW)

(72) Inventors: You-Liang Chou, Taichung City (TW); Wen-Che Tsai, Hualien City (TW)

(73) Assignee: MACRONIX International Co., Ltd., Hsinchu (TW)

(21) Appl. No.: 19/211,300

(22) Filed: May 19, 2025

(51) Int. Cl. G11C 16/04

(52) U.S. Cl. CPC G11C 16/0483

(57) ABSTRACT

A non-volatile memory applicable to a three-dimensional NAND flash memory with high capacity and high performance is provided. The non-volatile memory includes a memory cell string array and a control circuit. A first row, a second row, a third row, and a fourth row of the memory cell string array have different threshold voltage configurations for string selection cells. Each string selection line is coupled to a control terminal of a corresponding string selection cell in each memory cell string. In response to the string selection lines with a control voltage configuration turning on the string selection cells in one of the first, second, third and fourth rows, at least one of the string selection cells of each memory cell string in the other ones of the first, second, third and fourth rows is turned off.

### BACKGROUND

### Technical Field

The present disclosure relates to a memory circuit, and more particularly to a non-volatile memory using CbA (CMOS directly Bonded to Array) technology.

### Description of Related Art

Integrated circuits containing high-capacity and high-performance 3D NAND flash memory are continuously developing. To overcome the issue of size reduction, the NAND flash memory industry has transitioned from a planar architecture to a 3D architecture. The storage capacity of 3D vertical NAND flash memory has continuously increased over the past decade to meet the demands of various industries, including mobile devices and data centers. The increase in the number of stacked word-line (WL) layers has played a key role in achieving higher storage capacity or bit density. This paradigm shift allows an increase in storage density through the vertical stacking of storage cells rather than relying solely on cell miniaturization. Charge-trap technology adopts a continuous silicon nitride layer as a storage node (SN). Compared to floating gate technology, charge-trap technology has a simpler manufacturing process and higher vertical scalability, making it widely used in 3D NAND flash memory arrays.

With advancements in technology, the manufacturing of 3D NAND flash memory arrays has progressed from CnA (CMOS Near Array) technology and CuA (CMOS Under Array) technology to CbA (CMOS directly Bonded to Array) technology. The wiring connection method of the CbA memory cell string array differs from that of CnA and CuA. How to control the string selection cells of the CbA memory cell string array to select the memory cell strings of the CbA memory cell string array is one of the many technical issues in the field of flash memory.

### SUMMARY

The disclosure provides a non-volatile memory to a select memory cell string of a designated row.

In an embodiment of the disclosure, a non-volatile memory includes a memory cell string array and a control circuit. The memory cell string array includes multiple memory cell strings. Each memory cell string includes multiple string selection cells and multiple memory cells. Each string selection line is coupled to a control terminal of a corresponding string selection cell in each memory cell string. Each word line is coupled to a control terminal of a corresponding memory cell in each memory cell string. Each bit line is coupled to an upper end of each memory cell string in a corresponding column of the memory cell string array. A first common source line of multiple common source lines is coupled to a lower end of each memory cell string in a first row of the memory cell string array. The string selection cells of each memory cell string in the first row have a first threshold voltage configuration. A second common source line of the multiple common source lines is coupled to a lower end of each memory cell string in a second row of the memory cell string array. The string selection cells of each memory cell string in the second row have a second threshold voltage configuration. A third common source line of the multiple common source lines is coupled to a lower end of each memory cell string in a third row of the memory cell string array. The string selection cells of each memory cell string in the third row have a third threshold voltage configuration. A fourth common source line of the multiple common source lines is coupled to a lower end of each memory cell string in a fourth row of the memory cell string array. The string selection cells of each memory cell string in the fourth row have a fourth threshold voltage configuration. The first threshold voltage configuration, the second threshold voltage configuration, the third threshold voltage configuration, and the fourth threshold voltage configuration are different from one another. The control circuit is coupled to the string selection lines to control the string selection cells of the memory cell strings in the memory cell string array. In response to the string selection lines with a control voltage configuration turning on the string selection cells of each memory cell string in one of the first row, the second row, the third row, and the fourth row, at least one of the string selection cells of each memory cell string in the other ones of the first row, the second row, the third row, and the fourth row is turned off.

Based on the above, the memory cell string array described in the embodiments of the disclosure has multiple rows. Different rows have different threshold voltage configurations for the string selection cells. Based on the differences in the threshold voltage configurations of the string selection cells of the first row, the second row, the third row, and the fourth row, the control circuit may appropriately set a control voltage configuration of the multiple string selection lines to selectively turn on the memory cell strings of a designated row and turn off the memory cell strings of other rows.

To make the features and advantages of the disclosure more comprehensible, several embodiments accompanied with drawings are described in detail as follows.

### BRIEF DESCRIPTION OF THE DRAWINGS

FIG. 1 is a circuit block diagram of a non-volatile memory according to an embodiment of the disclosure.

FIG. 2 is a schematic diagram illustrating the threshold voltage composition of string selection cells according to an embodiment of the disclosure.

FIG. 3 is a circuit schematic diagram illustrating memory cell strings in different rows according to an embodiment of the disclosure.

FIG. 4 is a circuit schematic diagram illustrating memory cell strings in different rows according to another embodiment of the disclosure.

FIG. 5 is a circuit schematic diagram illustrating memory cell strings in different rows according to yet another embodiment of the disclosure.

FIG. 6 is a schematic diagram illustrating the threshold voltage distribution of string selection cells according to another embodiment of the disclosure.

FIG. 7 is a circuit schematic diagram illustrating memory cell strings in different rows according to still another embodiment of the disclosure.

FIG. 8 is a schematic diagram illustrating the threshold voltage distribution of string selection cells according to yet another embodiment of the disclosure.

FIG. 9 is a circuit schematic diagram illustrating memory cell strings in different rows according to yet another embodiment of the disclosure.

FIG. 10 is a schematic diagram illustrating the threshold voltage distribution of string selection cells according to a further embodiment of the disclosure.

FIG. 11 is a circuit schematic diagram illustrating memory cell strings in different rows according to a further embodiment of the disclosure.

### DESCRIPTION OF THE EMBODIMENTS

In the present specification (including the claims), the term “coupled to (or connected to)” may refer to any direct or indirect connection means. For example, if the text describes that a first device is coupled to (or connected to) a second device, it should be interpreted that the first device may be directly connected to the second device or that the first device may be indirectly connected to the second device through other devices or certain connection means. The terms “first,” “second,” and the like mentioned in the present specification (including the claims) are used to name elements or to distinguish different embodiments or ranges and are not intended to limit the upper or lower number of elements, nor to restrict the sequence of the elements. Additionally, where possible, elements/components/steps labeled with the same reference numerals in the drawings and embodiments represent the same or similar parts. Elements/components/steps using the same reference numerals or the same terminology in different embodiments may be cross-referenced to the relevant descriptions.

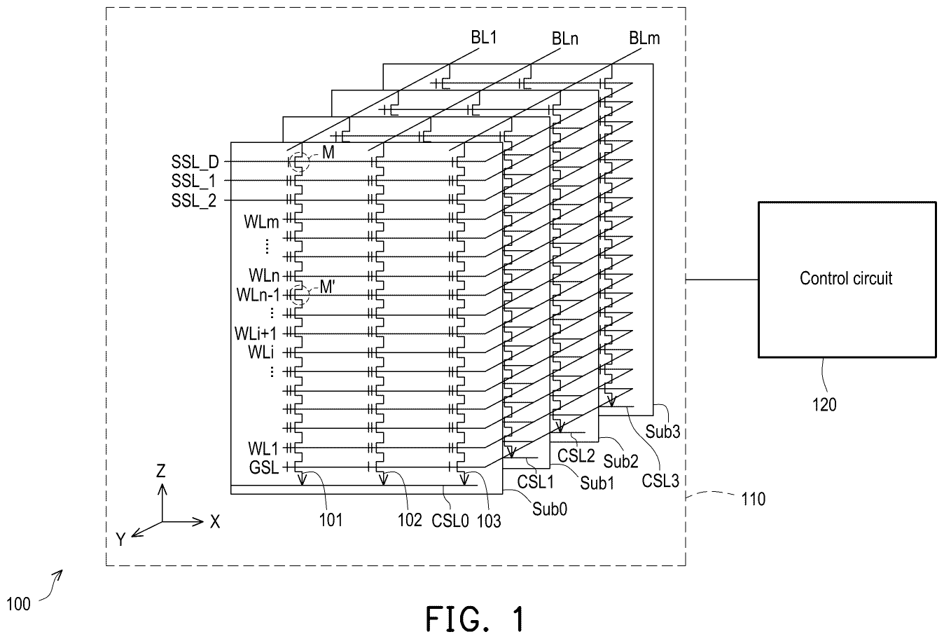

FIG. 1 is a circuit block diagram of a non-volatile memory 100 according to an embodiment of the disclosure. The non-volatile memory 100 includes a memory cell string array 110 and a control circuit 120. FIG. 1 illustrates an equivalent circuit of a three-dimensional (3D) NAND flash memory integrated circuit in a 3D manner. The memory cell string array 110 includes multiple memory cell strings (e.g., memory cell strings 101, 102, or 103), and each memory cell string includes multiple memory cells (e.g., a memory cell M′) that are serially connected along the Z direction. The multiple memory cells in the memory cell string array 110 shown in FIG. 1 are arranged in a 3D manner in the XYZ coordinate system. However, this does not mean that the circuit of the memory cell string array 110 is limited to a 3D arrangement. In one example, the memory cell string array 110 may be divided into four sub-blocks, Sub0, Sub1, Sub2, and Sub3. In this example, multiple memory cell strings (e.g., memory cell strings 101, 102, and 103) on the same plane (a plane defined by the X direction and the Z direction) may be defined as a sub-block (e.g., a sub-block Sub0).

The memory cell string array 110 includes multiple word lines (WLs), such as word lines WL1, . . . , WLi, WLi+1, . . . , WLn−1, WLn, . . . , and WLm shown in FIG. 1. The number of word lines in the memory cell string array 110 may be determined according to actual design and application. A word line (e.g., word line WLn) may correspond to a layer of the memory cell array (a plane defined by the X direction and the Y direction). Each of the word lines WL1 to WLm is coupled to a control terminal of a corresponding memory cell in each memory cell string. A string select line (SSL) SSL_D is coupled to a control terminal of an end switch cell of each memory cell string. For example, a control terminal of an end switch cell M of the memory cell string 101 is coupled to the string select line SSL_D. A ground select line (GSL) is coupled to a control terminal of a ground select transistor of each memory cell string. The end switch cell and the ground select transistor are located on opposite sides of each memory cell string (e.g., memory cell string 101).

The memory cell string array 110 further includes multiple bit lines (BLs), such as bit lines BL1, BLn, and BLm shown in FIG. 1. The number of bit lines in the memory cell string array 110 may be determined according to actual design and application. Each bit line is coupled to an upper end of each memory cell string in a corresponding column of the memory cell string array 110. For example, an upper end of the end switch cell M of the memory cell string 101 is coupled to the bit line BL1. Similarly, the bit line BLn is coupled to the upper end of each memory cell string in another column of the memory cell string array 110, and the bit line BLm is coupled to the upper end of each memory cell string in yet another column of the memory cell string array 110.

The memory cell string array 110 further includes multiple common source lines (CSLs), such as common source lines CSL0, CSL1, CSL2, and CSL3 shown in FIG. 1. The number of common source lines in the memory cell string array 110 may be determined according to actual design and application. Each common source line is coupled to a lower end of each memory cell string in a corresponding row of the memory cell string array 110. For example, the common source line CSL0 is coupled to the lower ends of the memory cell strings 101, 102, and 103 in the first row (e.g., the sub-block Sub0). Similarly, the common source line CSL1 is coupled to the lower ends of multiple memory cell strings in the second row (e.g., a sub-block Sub1), the common source line CSL2 is coupled to the lower ends of multiple memory cell strings in the third row (e.g., a sub-block Sub2), and the common source line CSL3 is coupled to the lower ends of multiple memory cell strings in the fourth row (e.g., a sub-block Sub3).

The memory cell string array 110 further includes multiple string selection lines, such as string selection lines SSL_1 and SSL_2 shown in FIG. 1. The number of string selection lines in the memory cell string array 110 may be determined according to actual design and application. For example, in other embodiments, the memory cell string array 110 includes three string selection lines SSL_1, SSL_2, and SSL_3 (not shown) or more string selection lines. Each of the string selection lines SSL_1 and SSL_2 is coupled to a control terminal of a corresponding string selection cell in each memory cell string. The implementation of the string selection cells is similar to that of the memory cells. The string selection cells in the same memory cell string have multiple threshold voltages. The threshold voltages of the string selection cells in the same memory cell string may be trimmed to multiple threshold voltage configurations. The string selection cells in different rows have different threshold voltage configurations. For example, the multiple string selection cells of each memory cell string in the first row (e.g., the sub-block Sub0) have a first threshold voltage configuration. Similarly, the multiple string selection cells of each memory cell string in the second row (e.g., the sub-block Sub1) have a second threshold voltage configuration, the multiple string selection cells of each memory cell string in the third row (e.g., the sub-block Sub2) have a third threshold voltage configuration, and the multiple string selection cells of each memory cell string in the fourth row (e.g., the sub-block Sub3) have a fourth threshold voltage configuration. The first threshold voltage configuration, the second threshold voltage configuration, the third threshold voltage configuration, and the fourth threshold voltage configuration are different from each other.

In one example, one or more dummy lines or layers (not shown) may be disposed between the string selection line (e.g., string selection line SSL_2) and the topmost word line layer (e.g., word line WLm), and between the ground selection line GSL and the bottommost word line layer (e.g., word line WL1). In another example, one or more dummy lines or layers (not shown) may be disposed in the middle portion of each memory cell string (e.g., memory cell string 101, 102, or 103).

The non-volatile memory 100 further includes a control circuit 120, used to implement corresponding operations of the memory cell string array 110. The control circuit 120 is coupled to the memory cell string array 110. Depending on different designs, in some embodiments, the implementation of the control circuit 120 may be a hardware circuit. In other embodiments, the implementation of the control circuit 120 may be a combination of multiple forms of hardware, firmware, and software (i.e., programs).

In terms of hardware, the control circuit 120 may be implemented as a logic circuit on an integrated circuit. For example, the relevant functions of the control circuit 120 may be implemented in one or more hardware controllers, microcontrollers, hardware processors, microprocessors, application-specific integrated circuits (ASICs), digital signal processors (DSPs), field-programmable gate arrays (FPGAs), central processing units (CPUs), and/or various logic blocks, modules, and circuits in other processing units. The relevant functions of the control circuit 120 may be implemented as a hardware circuit using a hardware description language (e.g., Verilog HDL or VHDL) or other suitable programming languages, such as various logic blocks, modules, and circuits in an integrated circuit.

In terms of software and/or firmware, the relevant functions of the control circuit 120 may be implemented as programming codes. For example, the control circuit 120 may be implemented using general programming languages (e.g., C, C++, or assembly language) or other suitable programming languages. The programming codes may be recorded/stored in a “non-transitory machine-readable storage medium.” In some embodiments, the non-transitory machine-readable storage medium may include semiconductor memory and/or storage devices. An electronic device (e.g., a CPU, a hardware controller, a microcontroller, a hardware processor, or a microprocessor) may read and execute the programming codes from the non-transitory machine-readable storage medium, thereby implementing the relevant functions of the control circuit 120.

The control circuit 120 is coupled to the string selection lines SSL_1 and SSL_2 to control multiple string selection cells of the memory cell strings in the memory cell string array 110. The string selection cells in different rows have different threshold voltage configurations. The control circuit 120 may appropriately set the control voltage configurations of the string selection lines SSL_1 and SSL_2. In response to the string selection lines SSL_1 and SSL_2 with the control voltage configuration turning on all string selection cells in each memory cell string of one of the first row, the second row, the third row, and the fourth row (e.g., sub-blocks Sub0, Sub1, Sub2, and Sub3), at least one of the multiple string selection cells in each memory cell string of the other ones of the first row, the second row, the third row, and the fourth row is turned off.

In summary, the memory cell string array 110 has multiple rows, where different rows have different threshold voltage configurations for the string selection cells. Based on the differences in the threshold voltage configurations of the string selection cells between the first row, the second row, the third row, and the fourth row (e.g., sub-blocks Sub0, Sub1, Sub2, and Sub3), the control circuit 120 may appropriately set the control voltage configurations of the string selection lines SSL_1 and SSL_2 to selectively turn on the memory cell strings in a designated row and turn off the memory cell strings in the other rows.

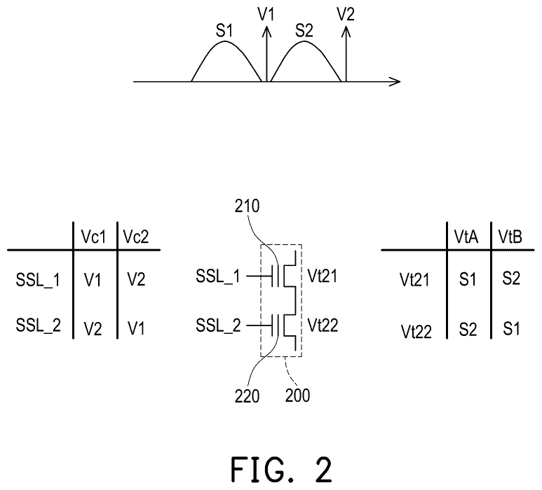

FIG. 2 is a schematic diagram illustrating the threshold voltage composition of the string selection cells according to an embodiment of the disclosure. The upper part of FIG. 2 shows a schematic diagram of the threshold voltage distribution of the string selection cells, where the horizontal axis represents the threshold voltage, and the vertical axis represents the number or probability of the string selection cells. In the embodiment shown in FIG. 2, the threshold voltage distribution of the string selection cells may be divided into threshold voltages S1 and S2, and the control voltage of the string selection lines includes voltage levels V1 and V2.

The lower part of FIG. 2 illustrates two string selection cells 210 and 220 in the same memory cell string. The string selection cells 210 and 220 belong to a same cell group 200. The string selection cells 210 and 220 shown in FIG. 2 serve as one of many implementation examples of any pair of string selection cells connected to the string selection lines SSL_1 and SSL_2 in FIG. 1. The threshold voltage Vt21 of the string selection cell 210 and the threshold voltage Vt22 of the string selection cell 220 may be trimmed to multiple threshold voltages (e.g., threshold voltages S1 and S2), and the threshold voltages Vt21 and Vt22 of the string selection cells 210 and 220 may be arranged in multiple threshold voltage compositions (e.g., threshold voltage compositions VtA and VtB). For example, the threshold voltage composition VtA is as follows: the threshold voltage Vt21 is trimmed to the threshold voltage S1, and the threshold voltage Vt22 is trimmed to a threshold voltage S2 that is higher than the threshold voltage S1. The threshold voltage composition VtB is as follows: the threshold voltage Vt21 is trimmed to the threshold voltage S2, and the threshold voltage Vt22 is trimmed to the threshold voltage S1.

The string selection lines SSL_1 and SSL_2 are respectively coupled to the control terminals of the string selection cells 210 and 220. The string selection lines SSL_1 and SSL_2 belong to the same line group. The control circuit 120 may set/adjust the control voltages of the string selection lines SSL_1 and SSL_2 to multiple voltage levels (e.g., voltage levels V1 and V2), and the string selection lines SSL_1 and SSL_2 may be set/adjusted to multiple control voltage configurations (e.g., control voltage configurations Vc1 and Vc2). For example, the control voltages of the line group include the voltage level V1 between the threshold voltage S1 and the threshold voltage S2, or the voltage level V2 greater than the threshold voltage S2. The control voltage configuration Vc1 is as follows: the control voltage of the string selection line SSL_1 is set to the voltage level V1, and the control voltage of the string selection line SSL_2 is set to the voltage level V2. The control voltage configuration Vc2 is as follows: the control voltage of the string selection line SSL_1 is set to the voltage level V2, and the control voltage of the string selection line SSL_2 is set to the voltage level V1. Based on the threshold voltage compositions of the string selection cells 210 and 220, the control circuit 120 may appropriately set the control voltage configurations of the string selection lines SSL_1 and SSL_2 to turn on the string selection cells 210 and 220, or turn off at least one of the string selection cells 210 and 220.

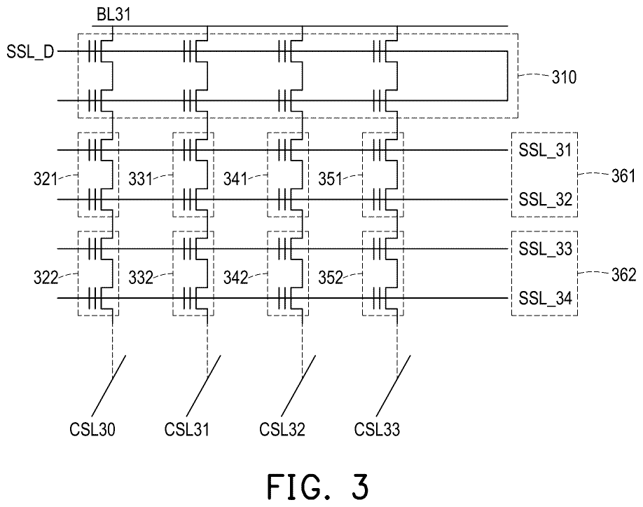

FIG. 3 is a circuit schematic diagram illustrating memory cell strings in different rows according to an embodiment of the disclosure. In the embodiment shown in FIG. 3, a common source line CSL30 is coupled to the lower ends of the memory cell strings in the first row, a common source line CSL31 is coupled to the lower ends of the memory cell strings in the second row, a common source line CSL32 is coupled to the lower ends of the memory cell strings in the third row, and a common source line CSL33 is coupled to the lower ends of the memory cell strings in the fourth row. A bit line BL31 is coupled to the upper ends of each memory cell string in a corresponding column of the memory cell string array 110. The bit line BL31, the string selection line SSL_D, an end switch cell 310, the common source line CSL30, the common source line CSL31, the common source line CSL32, and the common source line CSL33 shown in FIG. 3 may be referred to the related descriptions of the bit line BL1, the string selection line SSL_D, the end switch cell M, the common source line CSL0, the common source line CSL1, the common source line CSL2, and the common source line CSL3 shown in FIG. 1 and inferred accordingly. Therefore, further descriptions are omitted.

FIG. 3 illustrates four memory cell strings, each memory cell string having four string selection cells, and the string selection cells are divided into multiple cell groups. For example, the string selection cells of the memory cell strings in the first row are divided into cell groups 321 and 322, the string selection cells of the memory cell strings in the second row are divided into cell groups 331 and 332, the string selection cells of the memory cell strings in the third row are divided into cell groups 341 and 342, and the string selection cells of the memory cell strings in the fourth row are divided into cell groups 351 and 352. The string selection cells belonging to the same cell group have different threshold voltages. The threshold voltage compositions of the cell groups 321, 322, 331, 332, 341, 342, 351, and 352 include a first threshold voltage composition and a second threshold voltage composition that are different from each other (e.g., the threshold voltage compositions VtA and VtB shown in FIG. 2). Each of the cell groups 321, 322, 331, 332, 341, 342, 351, and 352 shown in FIG. 3 may be referred to the related descriptions of the cell group 200 shown in FIG. 2 and inferred accordingly.

In the embodiment shown in FIG. 3, the memory cell string array 110 includes multiple string selection lines SSL_31, SSL_32, SSL_33, and SSL_34. Each of the string selection lines SSL_31, SSL_32, SSL_33, and SSL_34 shown in FIG. 3 may be referred to the related descriptions of the string selection lines SSL_1 or SSL_2 shown in FIG. 2 and inferred accordingly. The string selection lines SSL_31, SSL_32, SSL_33, and SSL_34 are divided into multiple line groups 361 and 362. The string selection lines belonging to the same line group are coupled to the control terminals of different string selection cells in the same cell group. The control voltage configurations of the line groups 361 and 362 include a first control voltage configuration and a second control voltage configuration that are different from each other (e.g., the control voltage configurations Vc1 and Vc2 shown in FIG. 2).

TABLE 1
Relationship Between Control Voltage Configuration
and Threshold Voltage Composition

| | 361, 362 | | | |
|---|---|---|---|---|
| | Vc1, Vc1 | Vc2, Vc1 | Vc2, Vc2 | Vc1, Vc2 |
| 321, 322: VtA, VtA | ON | OFF | OFF | OFF |
| 331, 332: VtB, VtA | OFF | ON | OFF | OFF |
| 341, 342: VtB, VtB | OFF | OFF | ON | OFF |
| 351, 352: VtA, VtB | OFF | OFF | OFF | ON |

The above Table 1 is a relationship table between the control voltage configuration and the threshold voltage composition according to an embodiment of the disclosure, where the horizontal axis represents the control voltage configurations of the line groups 361 and 362, and the vertical axis represents the threshold voltage compositions of the cell groups 321, 322, 331, 332, 341, 342, 351, and 352. The threshold voltage compositions of the cell groups 321 and 322 in the first row are both the threshold voltage composition VtA. The threshold voltage compositions of the cell groups 331 and 332 in the second row are the threshold voltage compositions VtB and VtA, respectively. The threshold voltage compositions of the cell groups 341 and 342 in the third row are both the threshold voltage composition VtB. The threshold voltage compositions of the cell groups 351 and 352 in the fourth row are the threshold voltage compositions VtA and VtB, respectively.

In response to the control voltage configurations of the line groups 361 and 362 both being the control voltage configuration Vc1, the cell groups 321 and 322 in the first row are turned on, while at least one of the two cell groups in the other rows is turned off. In response to the control voltage configurations of the line groups 361 and 362 being the control voltage configurations Vc2 and Vc1, respectively, the cell groups 331 and 332 in the second row are turned on, while at least one of the two cell groups in the other rows is turned off. In response to the control voltage configurations of the line groups 361 and 362 both being the control voltage configuration Vc2, the cell groups 341 and 342 in the third row are turned on, while at least one of the two cell groups in the other rows is turned off. In response to the control voltage configurations of the line groups 361 and 362 being the control voltage configurations Vc1 and Vc2, respectively, the cell groups 351 and 352 in the fourth row are turned on, while at least one of the two cell groups in the other rows is turned off.

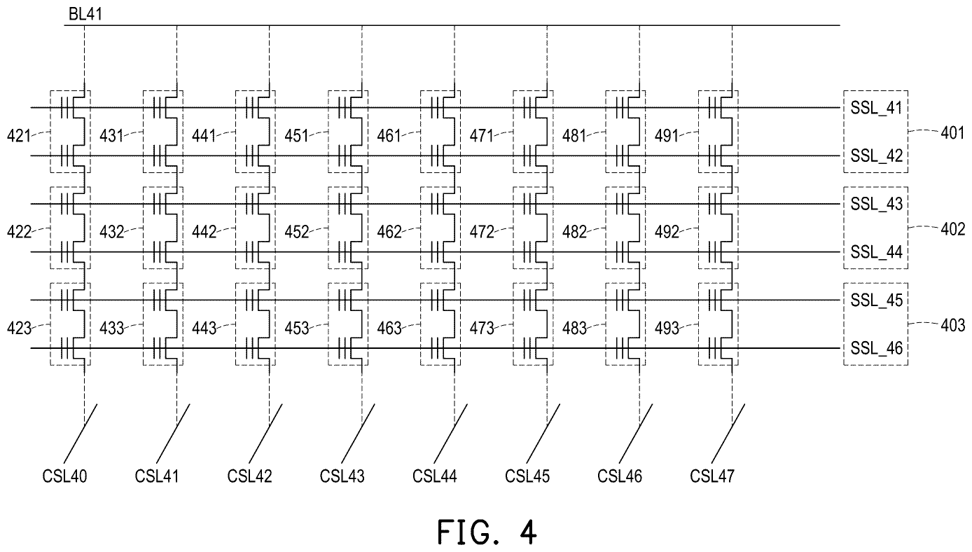

FIG. 4 is a circuit schematic diagram illustrating memory cell strings in different rows according to another embodiment of the disclosure. In the embodiment shown in FIG. 4, a common source line CSL40 is coupled to the lower ends of the memory cell strings in the first row, a common source line CSL41 is coupled to the lower ends of the memory cell strings in the second row, a common source line CSL42 is coupled to the lower ends of the memory cell strings in the third row, a common source line CSL43 is coupled to the lower ends of the memory cell strings in the fourth row, a common source line CSL44 is coupled to the lower ends of the memory cell strings in the fifth row, a common source line CSL45 is coupled to the lower ends of the memory cell strings in the sixth row, a common source line CSL46 is coupled to the lower ends of the memory cell strings in the seventh row, and a common source line CSL47 is coupled to the lower ends of the memory cell strings in the eighth row. A bit line BL41 is coupled to the upper end of each memory cell string in the corresponding column of the memory cell string array 110. The bit line BL41 and the common source lines CSL40 to CSL47 shown in FIG. 4 may be referred to the related descriptions of the bit line BL1 and the common source lines CSL0 to CSL3 shown in FIG. 1 and inferred accordingly. Therefore, further description is omitted.

FIG. 4 illustrates eight memory cell strings, where each memory cell string includes six string selection cells, and these string selection cells are divided into multiple cell groups. For example, the string selection cells of the memory cell strings in the first row are divided into cell groups 421, 422, and 423. The string selection cells of the memory cell strings in the second row are divided into cell groups 431, 432, and 433. The string selection cells of the memory cell strings in the third row are divided into cell groups 441, 442, and 443. The string selection cells of the memory cell strings in the fourth row are divided into cell groups 451, 452, and 453. The string selection cells of the memory cell strings in the fifth row are divided into cell groups 461, 462, and 463. The string selection cells of the memory cell strings in the sixth row are divided into cell groups 471, 472, and 473. The string selection cells of the memory cell strings in the seventh row are divided into cell groups 481, 482, and 483. The string selection cells of the memory cell strings in the eighth row are divided into cell groups 491, 492, and 493. The string selection cells belonging to the same cell group have different threshold voltages. The threshold voltage compositions of these cell groups include the first threshold voltage composition and the second threshold voltage composition, which differ from each other (e.g., the threshold voltage compositions VtA and VtB shown in FIG. 2). Each cell group shown in FIG. 4 may be referred to the related descriptions of the cell group 200 shown in FIG. 2 and inferred accordingly.

In the embodiment shown in FIG. 4, the memory cell string array 110 includes multiple string selection lines SSL_41, SSL_42, SSL_43, SSL_44, SSL_45, and SSL_46. Each of the string selection lines SSL_41 to SSL_46 shown in FIG. 4 may be referred to the related descriptions of the string selection lines SSL_1 or SSL_2 shown in FIG. 2 and inferred accordingly. These string selection lines SSL_41 to SSL_46 are divided into multiple line groups 401, 402, and 403. The string selection lines belonging to the same line group are coupled to the control terminals of different string selection cells in the same cell group. The control voltage configurations of these line groups 401 to 403 include the first control voltage configuration and the second control voltage configuration, which differ from each other (e.g., the control voltage configurations Vc1 and Vc2 shown in FIG. 2).

TABLE 2
Relationship Between Control Voltage Configuration
and Threshold Voltage Composition

401, 402, 403

| | Vc1, | Vc2, | Vc2, | Vc2, |
|---|---|---|---|---|
| | Vc1, | Vc1, | Vc2, | Vc1, |
| | Vc1 | Vc1 | Vc1 | Vc2 |
| 421, 422, 423: | ON | OFF | OFF | OFF |
| VtA, VtA, VtA | | | | |
| 431, 432, 433: | OFF | ON | OFF | OFF |
| VtB, VtA, VtA | | | | |
| 441, 442, 443: | OFF | OFF | ON | OFF |
| VtB, VtB, VtA | | | | |
| 451, 452, 453: | OFF | OFF | OFF | ON |
| VtB, VtA, VtB | | | | |
| 461, 462, 463: | OFF | OFF | OFF | OFF |
| VtA, VtB, VtB | | | | |
| 471, 472, 473: | OFF | OFF | OFF | OFF |
| VtA, VtB, VtA | | | | |
| 481, 482, 483: | OFF | OFF | OFF | OFF |
| VtA, VtA, VtB | | | | |
| 491, 492, 493: | OFF | OFF | OFF | OFF |
| VtB, VtB, VtB | | | | |

401, 402, 403

| | Vc1, | Vc1, | Vc1, | Vc2, |
|---|---|---|---|---|
| | Vc2, | Vc2, | Vc1, | Vc2, |
| | Vc2 | Vc1 | Vc2 | Vc2 |
| 421, 422, 4 23: | OFF | OFF | OFF | OFF |
| VtA, VtA, VtA | | | | |
| 431, 432, 433: | OFF | OFF | OFF | OFF |
| VtB, VtA, VtA | | | | |
| 441, 442, 443: | OFF | OFF | OFF | OFF |
| VtB, VtB, VtA | | | | |
| 451, 452, 453: | OFF | OFF | OFF | OFF |
| VtB, VtA, VtB | | | | |
| 461, 462, 463: | ON | OFF | OFF | OFF |
| VtA, VtB, VtB | | | | |
| 471, 472, 473: | OFF | ON | OFF | OFF |
| VtA, VtB, VtA | | | | |
| 481, 482, 483: | OFF | OFF | ON | OFF |
| VtA, VtA, VtB | | | | |
| 491, 492, 493: | OFF | OFF | OFF | ON |
| VtB, VtB, VtB | | | | |

Table 2 represents the relationship between the control voltage configuration and the threshold voltage composition according to another embodiment of the disclosure. The horizontal axis represents the control voltage configurations of line groups 401 to 403, while the vertical axis represents the threshold voltage compositions of cell groups 421, 422, 423, 431, 432, 433, 441, 442, 443, 451, 452, 453, 461, 462, 463, 471, 472, 473, 481, 482, 483, 491, 492, and 493. The threshold voltage compositions of cell groups 421, 422, and 423 in the first row are all configured as threshold voltage composition VtA. The threshold voltage compositions of cell groups 431, 432, and 433 in the second row are configured as threshold voltage compositions VtB, VtA, and VtA, respectively. The threshold voltage compositions of cell groups 441, 442, and 443 in the third row are configured as threshold voltage compositions VtB, VtB, and VtA, respectively. The threshold voltage compositions of cell groups 451, 452, and 453 in the fourth row are configured as threshold voltage compositions VtB, VtA, and VtB, respectively. The threshold voltage compositions of cell groups 461, 462, and 463 in the fifth row are configured as threshold voltage compositions VtA, VtB, and VtB, respectively. The threshold voltage compositions of cell groups 471, 472, and 473 in the sixth row are configured as threshold voltage compositions VtA, VtB, and VtA, respectively. The threshold voltage compositions of cell groups 481, 482, and 483 in the seventh row are configured as threshold voltage compositions VtA, VtA, and VtB, respectively. The threshold voltage compositions of cell groups 491, 492, and 493 in the eighth row are all configured as threshold voltage composition VtB.

In response to the control voltage configurations of line groups 401 to 403 all being set to control voltage configuration Vc1, cell groups 421, 422, and 423 in the first row are turned on, while at least one of the three cell groups in the other rows is turned off. In response to the control voltage configurations of line groups 401 to 403 being set to control voltage configurations Vc2, Vc1, and Vc1, respectively, cell groups 431, 432, and 433 in the second row are turned on, while at least one of the three cell groups in the other rows is turned off. In response to the control voltage configurations of line groups 401 to 403 being set to control voltage configurations Vc2, Vc2, and Vc1, respectively, cell groups 441, 442, and 443 in the third row are turned on, while at least one of the three cell groups in the other rows is turned off. In response to the control voltage configurations of line groups 401 to 403 being set to control voltage configurations Vc2, Vc1, and Vc2, respectively, cell groups 451, 452, and 453 in the fourth row are turned on, while at least one of the three cell groups in the other rows is turned off. In response to the control voltage configurations of line groups 401 to 403 being set to control voltage configurations Vc1, Vc2, and Vc2, respectively, cell groups 461, 462, and 463 in the fifth row are turned on, while at least one of the three cell groups in the other rows is turned off. In response to the control voltage configurations of line groups 401 to 403 being set to control voltage configurations Vc1, Vc2, and Vc1, respectively, cell groups 471, 472, and 473 in the sixth row are turned on, while at least one of the three cell groups in the other rows is turned off. In response to the control voltage configurations of line groups 401 to 403 being set to control voltage configurations Vc1, Vc1, and Vc2, respectively, cell groups 481, 482, and 483 in the seventh row are turned on, while at least one of the three cell groups in the other rows is turned off. In response to the control voltage configurations of line groups 401 to 403 all being set to the second control voltage configuration Vc2, cell groups 491, 492, and 493 in the eighth row are turned on, while at least one of the three cell groups in the other rows is turned off.

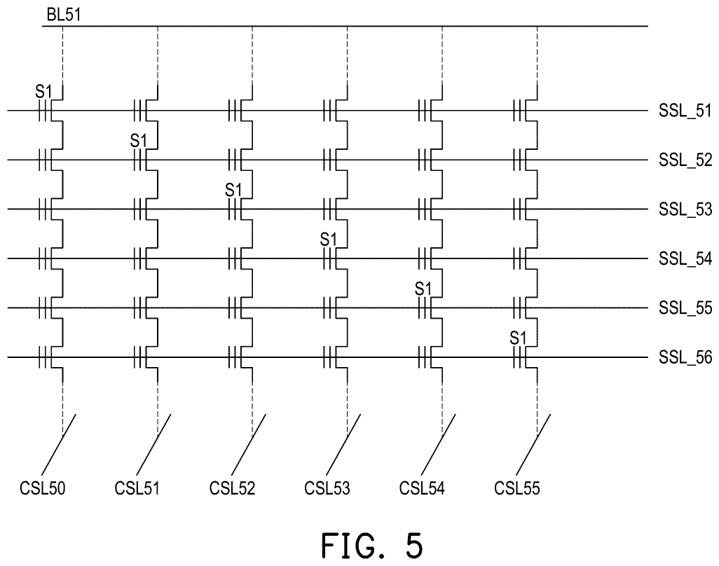

FIG. 5 is a circuit schematic diagram illustrating memory cell strings in different rows according to another embodiment of the disclosure. In the embodiment shown in FIG. 5, a common source line CSL50 is electrically connected to the lower ends of the memory cell strings in the first row. A common source line CSL51 is electrically connected to the lower ends of the memory cell strings in the second row. A common source line CSL52 is electrically connected to the lower ends of the memory cell strings in the third row. A common source line CSL53 is electrically connected to the lower ends of the memory cell strings in the fourth row. A common source line CSL54 is electrically connected to the lower ends of the memory cell strings in the fifth row. A common source line CSL55 is electrically connected to the lower ends of the memory cell strings in the sixth row. A bit line BL51 is electrically connected to the upper end of each memory cell string in the corresponding column of the memory cell string array 110. The bit line BL51 and the common source lines CSL50 to CSL55 shown in FIG. 5 may be referred to the descriptions of the bit line BL1 and the common source lines CSL0 to CSL3 shown in FIG. 1 and inferred accordingly. Thus, further details are omitted.

FIG. 5 illustrates six memory cell strings, each of which includes six string selection cells. One of the multiple string selection cells in each memory cell string is configured with a first threshold voltage (e.g., the threshold voltage S1 shown in FIG. 2). The other string selection cells are configured with a second threshold voltage higher than the first threshold voltage (e.g., the threshold voltage S2 shown in FIG. 2). As shown in FIG. 5, the position of the string selection cell configured with the threshold voltage S1 in the memory cell string of the first row differs from the position of the string selection cell configured with the threshold voltage S1 in the memory cell string of the second row. The position of the string selection cell configured with the threshold voltage S1 in the memory cell string of the second row differs from the position of the string selection cell configured with the threshold voltage S1 in the memory cell string of the third row. The position of the string selection cell configured with the threshold voltage S1 in the memory cell string of the third row differs from the position of the string selection cell configured with the threshold voltage S1 in the memory cell string of the fourth row.

The multiple string selection lines of the memory cell string array 110 include: a string selection line SSL_51 electrically connected to the first string selection cell of the multiple string selection cells of all memory cell strings, a string selection line SSL_52 electrically connected to the second string selection cell of these string selection cells of all memory cell strings, a string selection line SSL_53 electrically connected to the third string selection cell of these string selection cells of all memory cell strings, a string selection line SSL_54 electrically connected to the fourth string selection cell of these string selection cells of all memory cell strings, a string selection line SSL_55 electrically connected to the fifth string selection cell of these string selection cells of all memory cell strings, and a string selection line SSL_56 electrically connected to the sixth string selection cell of these string selection cells of all memory cell strings.

As shown in FIG. 5, in the memory cell string of the first row, the first string selection cell is configured with the threshold voltage S1, while the other string selection cells are configured with the threshold voltage S2. In the memory cell string of the second row, the second string selection cell is configured with the threshold voltage S1, while the other string selection cells are configured with the threshold voltage S2. In the memory cell string of the third row, the third string selection cell is configured with the threshold voltage S1, while the other string selection cells are configured with the threshold voltage S2. In the memory cell string of the fourth row, the fourth string selection cell is configured with the threshold voltage S1, while the other string selection cells are configured with the threshold voltage S2. In the memory cell string of the fifth row, the fifth string selection cell is configured with the threshold voltage S1, while the other string selection cells are configured with the threshold voltage S2. In the memory cell string of the sixth row, the sixth string selection cell is configured with the threshold voltage S1, while the other string selection cells are configured with the threshold voltage S2.

In response to the control voltage of the string selection line SSL_51 being set to the voltage level V1, which is between the threshold voltages S1 and S2 (while the control voltage of the other string selection lines is set to the voltage level V2, which is greater than the threshold voltage S2), all the string selection cells of the memory cell string in the first row are turned on, whereas at least one of the multiple string selection cells in each memory cell string of the other rows is turned off. In response to the control voltage of the string selection line SSL_52 being set to the voltage level V1 (while the control voltage of the other string selection lines is set to the voltage level V2), all the string selection cells of the memory cell string in the second row are turned on, whereas at least one of the multiple string selection cells in each memory cell string of the other rows is turned off. In response to the control voltage of the string selection line SSL_53 being set to the voltage level V1 (while the control voltage of the other string selection lines is set to the voltage level V2), all the string selection cells of the memory cell string in the third row are turned on, whereas at least one of the multiple string selection cells in each memory cell string of the other rows is turned off. In response to the control voltage of the string selection line SSL_54 being set to the voltage level V1 (while the control voltage of the other string selection lines is set to the voltage level V2), all the string selection cells of the memory cell string in the fourth row are turned on, whereas at least one of the multiple string selection cells in each memory cell string of the other rows is turned off. In response to the control voltage of the string selection line SSL_55 being set to the voltage level V1 (while the control voltage of the other string selection lines is set to the voltage level V2), all the string selection cells of the memory cell string in the fifth row are turned on, whereas at least one of the multiple string selection cells in each memory cell string of the other rows is turned off. In response to the control voltage of the string selection line SSL_56 being set to the voltage level V1 (while the control voltage of the other string selection lines is set to the voltage level V2), all the string selection cells of the memory cell string in the sixth row are turned on, whereas at least one of the multiple string selection cells in each memory cell string of the other rows is turned off.

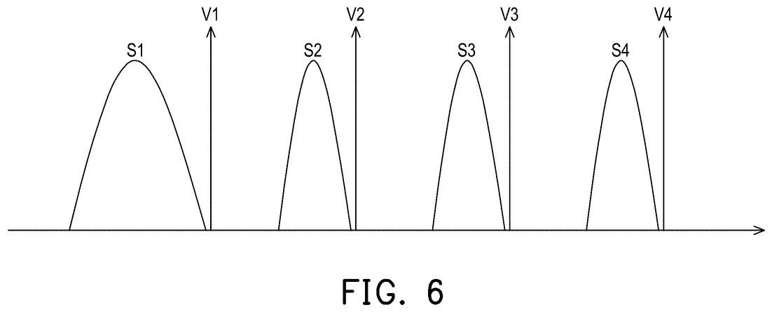

FIG. 6 is a schematic diagram illustrating the threshold voltage distribution of string selection cells according to another embodiment of the disclosure. The horizontal axis of FIG. 6 represents the threshold voltage, and the vertical axis represents the number of string selection cells or probability. In the embodiment shown in FIG. 6, the threshold voltage distribution of the string selection cells may be categorized into threshold voltages S1, S2, S3, and S4, while the control voltage of the string selection lines includes voltage levels V1, V2, V3, and V4.

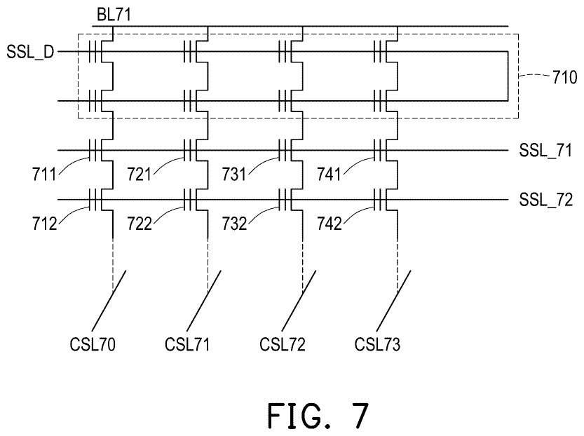

FIG. 7 is a circuit schematic diagram illustrating memory cell strings in different rows according to yet another embodiment of the disclosure. In the embodiment shown in FIG. 7, a common source line CSL70 is electrically connected to the lower ends of the memory cell strings in the first row, a common source line CSL71 is electrically connected to the lower ends of the memory cell strings in the second row, a common source line CSL72 is electrically connected to the lower ends of the memory cell strings in the third row, and a common source line CSL73 is electrically connected to the lower ends of the memory cell strings in the fourth row. A bit line BL71 is electrically connected to the upper ends of each memory cell string in a corresponding column of the memory cell string array 110. The bit line BL71, the string selection line SSL_D, an end switch cell 710, the common source line CSL70, the common source line CSL71, the common source line CSL72, and the common source line CSL73 shown in FIG. 7 may be referenced to the descriptions of the bit line BL1, the string selection line SSL_D, the end switch cell M, the common source line CSL0, the common source line CSL1, the common source line CSL2, and the common source line CSL3 shown in FIG. 1, and analogy may be made accordingly, so detailed description thereof is omitted.

FIG. 7 illustrates four memory cell strings, where each memory cell string includes two string selection cells. Referring to FIGS. 6 and 7, these string selection cells are trimmed to have multiple threshold voltages that differ from each other (e.g., threshold voltages S1, S2, S3, and S4). These threshold voltages S1 to S4 are grouped into multiple threshold voltage pairs, where the upper threshold voltage and the lower threshold voltage of a first threshold voltage pair are both positioned between the upper threshold voltage and the lower threshold voltage of a second threshold voltage pair. For example, threshold voltage S2 and threshold voltage S3 form the lower and upper threshold voltages of the first threshold voltage pair, while threshold voltage S1 and threshold voltage S4 form the lower and upper threshold voltages of the second threshold voltage pair. Correspondingly, the control circuit 120 outputs control voltages to the string selection cells via the string selection lines SSL_1 and SSL_2 at voltage levels V1, V2, V3, and V4, which are also grouped into multiple control voltage pairs. In these control voltage pairs, the upper voltage level and the lower voltage level of a first control voltage pair are both positioned between the upper voltage level and the lower voltage level of a second control voltage pair. For example, voltage levels V2 and V3 form the lower and upper voltage levels of the first control voltage pair, while voltage levels V1 and V4 form the lower and upper voltage levels of the second control voltage pair.

In each memory cell string belonging to the same row, the string selection cell pairs are trimmed to different threshold voltages within one of the corresponding threshold voltage pairs. For example, but not limited thereto, in the memory cell strings of the first row, a string selection cell pair of 711 and 712 is trimmed to different threshold voltages of the threshold voltage pair of S1 and S4 (e.g., the string selection cell 711 is trimmed to the threshold voltage S4, while the string selection cell 712 is trimmed to the threshold voltage S1). The threshold voltages of string selection cells 721 and 722 in the memory cell strings of the second row are threshold voltages S2 and S3, respectively. The threshold voltages of string selection cells 731 and 732 in the memory cell strings of the third row are threshold voltages S3 and S2, respectively. The threshold voltages of string selection cells 741 and 742 in the memory cell strings of the fourth row are threshold voltages S1 and S4, respectively.

In the embodiment shown in FIG. 7, the memory cell string array 110 includes multiple string selection lines SSL_71 and SSL_72. Each of the string selection lines SSL_71 and SSL_72 shown in FIG. 7 may refer to the description of the string selection lines SSL_1 or SSL_2 shown in FIG. 1 and be inferred accordingly. The string selection line SSL_71 is coupled to the control terminal of the first string selection cell in all memory cell strings. The string selection line SSL_72 is coupled to the control terminal of the second string selection cell in all memory cell strings. The control circuit 120 outputs control voltages (e.g., voltage levels V2 and V3 shown in FIG. 6, or voltage levels V1 and V4) to the control terminals of the string selection cells via the string selection lines SSL_71 and SSL_72.

TABLE 3
Relationship Between Control Voltage Configuration
and Threshold Voltage Configuration

SSL_71, SSL_72

| | V4, V1 | V2, V3 | V3, V2 | V1, V4 |
|---|---|---|---|---|
| 711, 712: S4, S1 | ON | OFF | OFF | OFF |
| 721, 722: S2, S3 | OFF | ON | OFF | OFF |
| 731, 732: S3, S2 | OFF | OFF | ON | OFF |
| 741, 742: S1, S4 | OFF | OFF | OFF | ON |

The above Table 3 is a relationship table of the control voltage configuration and the threshold voltage configuration according to another embodiment of the disclosure. The horizontal axis represents the control voltage configuration of the string selection lines SSL_71 and SSL_72, while the vertical axis represents the threshold voltage configuration of the string selection cells 711, 712, 721, 722, 731, 732, 741, and 742. The threshold voltages of the string selection cells 711 and 712 in the first row are threshold voltages S4 and S1, respectively. The threshold voltages of the string selection cells 721 and 722 in the second row are threshold voltages S2 and S3, respectively. The threshold voltages of the string selection cells 731 and 732 in the third row are threshold voltages S3 and S2, respectively. The threshold voltages of the string selection cells 741 and 742 in the fourth row are threshold voltages S1 and S4, respectively.

In response to the control voltage of the string selection line SSL_71 being a voltage level V4 greater than the threshold voltage S4 and the control voltage of the string selection line SSL_72 being a voltage level V1 between the threshold voltage S1 and the threshold voltage S2, the string selection cells 711 and 712 of the first row of memory cell strings are turned on, while at least one of the two string selection cells in the memory cell strings of the other rows is turned off. In response to the control voltage of the string selection line SSL_71 being a voltage level V2 between the threshold voltage S2 and the threshold voltage S3, and the control voltage of the string selection line SSL_72 being a voltage level V3 between the threshold voltage S3 and the threshold voltage S4, the string selection cells 721 and 722 of the second row of memory cell strings are turned on, while at least one of the two string selection cells in the memory cell strings of the other rows is turned off. In response to the control voltage of the string selection line SSL_71 being the voltage level V3 and the control voltage of the string selection line SSL_72 being the voltage level V2, the string selection cells 731 and 732 of the third row of memory cell strings are turned on, while at least one of the two string selection cells in the memory cell strings of the other rows is turned off. In response to the control voltage of the string selection line SSL_71 being the voltage level V1 and the control voltage of the string selection line SSL_72 being the voltage level V4, the string selection cells 741 and 742 of the fourth row of memory cell strings are turned on, while at least one of the two string selection cells in the memory cell strings of the other rows is turned off.

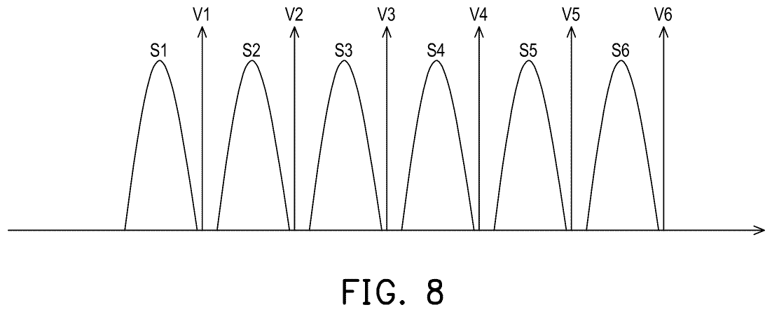

FIG. 8 is a schematic diagram illustrating the threshold voltage distribution of string selection cells according to another embodiment of the disclosure. The horizontal axis of FIG. 8 represents the threshold voltage, while the vertical axis represents the number or probability of string selection cells. In the embodiment shown in FIG. 8, the threshold voltage distribution of the string selection cells may be divided into threshold voltages S1, S2, S3, S4, S5, and S6, while the control voltage of the string selection lines includes voltage levels V1, V2, V3, V4, V5, and V6.

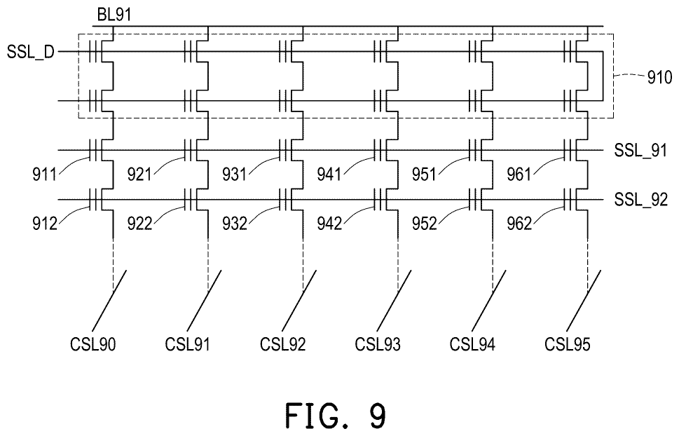

FIG. 9 is a schematic diagram illustrating the circuit of memory cell strings in different rows according to another embodiment of the disclosure. In the embodiment shown in FIG. 9, a common source line CSL90 is electrically connected to the lower end of the memory cell strings in the first row. A common source line CSL91 is electrically connected to the lower end of the memory cell strings in the second row. A common source line CSL92 is electrically connected to the lower end of the memory cell strings in the third row. A common source line CSL93 is electrically connected to the lower end of the memory cell strings in the fourth row. A common source line CSL94 is electrically connected to the lower end of the memory cell strings in the fifth row. A common source line CSL95 is electrically connected to the lower end of the memory cell strings in the sixth row. A bit line BL91 is electrically connected to the upper end of each memory cell string in the corresponding column of the memory cell string array 110. The bit line BL91, the string selection line SSL_D, an end switch cell 910, the common source line CSL90, the common source line CSL91, the common source line CSL92, the common source line CSL93, the common source line CSL94, and the common source line CSL95 shown in FIG. 9 may be referenced and analogized from the bit line BL1, the string selection line SSL_D, the end switch cell M, the common source line CSL0, the common source line CSL1, the common source line CSL2, and the common source line CSL3 shown in FIG. 1, and therefore are not redundantly described.

FIG. 9 illustrates six memory cell strings, where each memory cell string includes two string selection cells. Referring to FIGS. 8 and 9, these string selection cells are trimmed to different threshold voltages (e.g., threshold voltages S1, S2, S3, S4, S5, and S6). These threshold voltages S1 to S6 are divided into multiple threshold voltage pairs, where the upper threshold voltage and the lower threshold voltage of the first threshold voltage pair are both located between the upper threshold voltage and the lower threshold voltage of the second threshold voltage pair, and the upper threshold voltage and the lower threshold voltage of the second threshold voltage pair are both located between the upper threshold voltage and the lower threshold voltage of the third threshold voltage pair. For example, the threshold voltage S3 and the threshold voltage S4 are the lower threshold voltage and the upper threshold voltage of the first threshold voltage pair. The threshold voltage S2 and the threshold voltage S5 are the lower threshold voltage and the upper threshold voltage of the second threshold voltage pair. The threshold voltage S1 and the threshold voltage S6 are the lower threshold voltage and the upper threshold voltage of the third threshold voltage pair. Correspondingly, the control circuit 120 outputs control voltages to the string selection cells through the string selection lines SSL_1 and SSL_2. The voltage levels V1, V2, V3, V4, V5, and V6 are also divided into multiple control voltage pairs, where the upper voltage level and the lower voltage level of the first control voltage pair are both located between the upper voltage level and the lower voltage level of the second control voltage pair, and the upper voltage level and the lower voltage level of the second control voltage pair are both located between the upper voltage level and the lower voltage level of the third control voltage pair. For example, the voltage level V3 and the voltage level V4 are the lower voltage level and the upper voltage level of the first control voltage pair. The voltage level V2 and the voltage level V5 are the lower voltage level and the upper voltage level of the second control voltage pair. The voltage level V1 and the voltage level V6 are the lower voltage level and the upper voltage level of the third control voltage pair.

In each memory cell string belonging to the same row, the string selection cell pair is trimmed to different threshold voltages from one of the multiple threshold voltage pairs. For example (but not limited to this), a string selection cell pair of 911 and 912 in the memory cell string of the first row is trimmed to different threshold voltages from a threshold voltage pair of S1 and S6 (e.g., the string selection cell 911 is trimmed to the threshold voltage S6, while the string selection cell 912 is trimmed to the threshold voltage S1). The threshold voltages of string selection cells 921 and 922 in the memory cell string of the second row are threshold voltages S5 and S2, respectively. The threshold voltages of string selection cells 931 and 932 in the memory cell string of the third row are threshold voltages S4 and S3, respectively. The threshold voltages of string selection cells 941 and 942 in the memory cell string of the fourth row are threshold voltages S3 and S4, respectively. The threshold voltages of string selection cells 951 and 952 in the memory cell string of the fifth row are threshold voltages S2 and S5, respectively. The threshold voltages of string selection cells 961 and 962 in the memory cell string of the sixth row are threshold voltages S1 and S6, respectively.

In the embodiment shown in FIG. 9, the memory cell string array 110 includes multiple string selection lines SSL_91 and SSL_92. Each of the string selection lines SSL_91 and SSL_92 shown in FIG. 9 may be referred to the corresponding descriptions of the string selection lines SSL_1 or SSL_2 shown in FIG. 1 and inferred accordingly. The string selection line SSL_91 is coupled to the control terminal of the first string selection cell in each memory cell string. The string selection line SSL_92 is coupled to the control terminal of the second string selection cell in each memory cell string. The control circuit 120 outputs control voltages (e.g., the voltage levels V3 and V4, or the voltage levels V2 and V5, or the voltage levels V1 and V6 shown in FIG. 8) to the control terminals of the string selection cells through the string selection lines SSL_91 and SSL_92.

TABLE 4
Relationship Between Control Voltage Configuration
and Threshold Voltage Configuration

| | SSL_91, SSL_92 | | | | | |
|---|---|---|---|---|---|---|
| | V6, | V5, | V4, | V3, | V2, | V1, |
| | V1 | V2 | V3 | V4 | V5 | V6 |
| 911, 912:S6, S1 | ON | OFF | OFF | OFF | OFF | OFF |
| 921, 922:S5, S2 | OFF | ON | OFF | OFF | OFF | OFF |
| 931, 932:S4, S3 | OFF | OFF | ON | OFF | OFF | OFF |
| 941, 942:S3, S4 | OFF | OFF | OFF | ON | OFF | OFF |
| 951, 952:S2, S5 | OFF | OFF | OFF | OFF | ON | OFF |
| 961, 962:S1, S6 | OFF | OFF | OFF | OFF | OFF | ON |

The above Table 4 is a relationship table of control voltage configuration and threshold voltage configuration according to another embodiment of the present disclosure. In Table 4, the horizontal axis represents the control voltage configuration of the string selection lines SSL_91 and SSL_92, and the vertical axis represents the threshold voltage configuration of the string selection cells 911, 912, 921, 922, 931, 932, 941, 942, 951, 952, 961, and 962. The threshold voltages of the string selection cells 911 and 912 in the first row are threshold voltages S6 and S1, respectively. The threshold voltages of the string selection cells 921 and 922 in the second row are threshold voltages S5 and S2, respectively. The threshold voltages of the string selection cells 931 and 932 in the third row are threshold voltages S4 and S3, respectively. The threshold voltages of the string selection cells 941 and 942 in the fourth row are threshold voltages S3 and S4, respectively. The threshold voltages of the string selection cells 951 and 952 in the fifth row are threshold voltages S2 and S5, respectively. The threshold voltages of the string selection cells 961 and 962 in the sixth row are threshold voltages S1 and S6, respectively.

In response to the control voltage of the string selection line SSL_91 being a voltage level V6 greater than the threshold voltage S6 and the control voltage of the string selection line SSL_92 being a voltage level V1 between the threshold voltage S1 and S2, the string selection cells 911 and 912 of the first row of memory cell strings are turned on, while at least one of the two string selection cells in the memory cell strings of the other rows is turned off. In response to the control voltage of the string selection line SSL_91 being a voltage level V5 between the threshold voltage S5 and S6 and the control voltage of the string selection line SSL_92 being a voltage level V2 between the threshold voltage S2 and S3, the string selection cells 921 and 922 of the second row of memory cell strings are turned on, while at least one of the two string selection cells in the memory cell strings of the other rows is turned off. In response to the control voltage of the string selection line SSL_91 being a voltage level V4 between the threshold voltage S4 and S5 and the control voltage of the string selection line SSL_92 being a voltage level V3 between the threshold voltage S3 and S4, the string selection cells 931 and 932 of the third row of memory cell strings are turned on, while at least one of the two string selection cells in the memory cell strings of the other rows is turned off. In response to the control voltage of the string selection line SSL_91 being a voltage level V3 and the control voltage of the string selection line SSL_92 being a voltage level V4, the string selection cells 941 and 942 of the fourth row of memory cell strings are turned on, while at least one of the two string selection cells in the memory cell strings of the other rows is turned off. In response to the control voltage of the string selection line SSL_91 being a voltage level V2 and the control voltage of the string selection line SSL_92 being a voltage level V5, the string selection cells 951 and 952 of the fifth row of memory cell strings are turned on, while at least one of the two string selection cells in the memory cell strings of the other rows is turned off. In response to the control voltage of the string selection line SSL_91 being a voltage level V1 and the control voltage of the string selection line SSL_92 being a voltage level V6, the string selection cells 961 and 962 of the sixth row of memory cell strings are turned on, while at least one of the two string selection cells in the memory cell strings of the other rows is turned off.

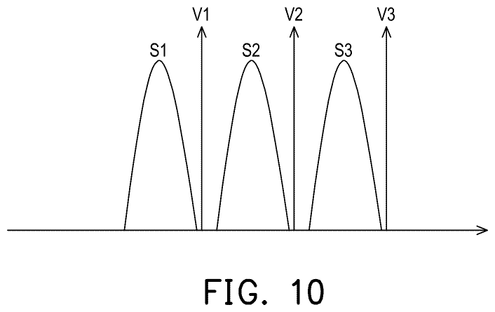

FIG. 10 is a schematic diagram illustrating the threshold voltage distribution of the string selection cells according to another embodiment of the present disclosure. The horizontal axis of FIG. 10 represents the threshold voltage, while the vertical axis represents the number or probability of the string selection cells. In the embodiment shown in FIG. 10, the threshold voltage distribution of the string selection cells may be classified into threshold voltages S1, S2, and S3, while the control voltage of the string selection lines includes voltage levels V1, V2, and V3.

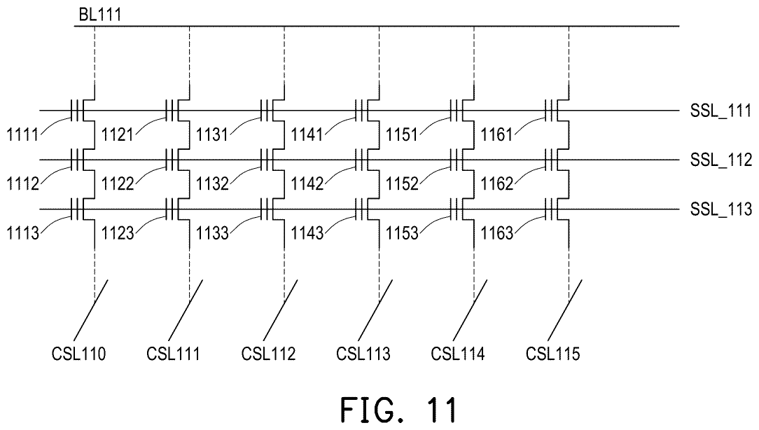

FIG. 11 is a schematic diagram illustrating the circuit of memory cell strings in different rows according to another embodiment of the present disclosure. In the embodiment shown in FIG. 11, a common source line CSL110 is electrically connected to the lower ends of the memory cell strings in the first row, a common source line CSL111 is electrically connected to the lower ends of the memory cell strings in the second row, a common source line CSL112 is electrically connected to the lower ends of the memory cell strings in the third row, a common source line CSL113 is electrically connected to the lower ends of the memory cell strings in the fourth row, a common source line CSL114 is electrically connected to the lower ends of the memory cell strings in the fifth row, and a common source line CSL115 is electrically connected to the lower ends of the memory cell strings in the sixth row. A bit line BL111 is electrically connected to the upper end of each memory cell string in the corresponding column of the memory cell string array 110. The bit line BL111, the common source line CSL110, the common source line CSL111, the common source line CSL112, the common source line CSL113, the common source line CSL114, and the common source line CSL115 shown in FIG. 11 may refer to the related descriptions of the bit line BL1, the common source line CSL0, the common source line CSL1, the common source line CSL2, and the common source line CSL3 shown in FIG. 1 and may be inferred accordingly, and thus, redundant descriptions are omitted.

FIG. 11 illustrates six memory cell strings, each including three string selection cells. In the embodiment shown in FIG. 11, the memory cell string array 110 includes multiple string selection lines SSL_111, SSL_112, and SSL_113. Each of the string selection lines SSL_111, SSL_112, and SSL_113 shown in FIG. 11 may refer to the related descriptions of the string selection lines SSL_1 or SSL_2 shown in FIG. 1 and may be inferred accordingly. The string selection line SSL_111 is electrically connected to the control terminals of the first string selection cells in all memory cell strings. The string selection line SSL_112 is electrically connected to the control terminals of the second string selection cells in all memory cell strings. The string selection line SSL_113 is electrically connected to the control terminals of the third string selection cells in all memory cell strings. The control circuit 120 outputs control voltages (e.g., the voltage levels V1, V3, and V4 shown in FIG. 10) through the string selection lines SSL_111, SSL_112, and SSL_113 to the control terminals of the string selection cells. The following Table 5 is a relationship table of the control voltage configuration and the threshold voltage configuration according to another embodiment of the present disclosure, where the horizontal axis represents the control voltage configuration of the string selection lines SSL_111, SSL_112, and SSL_113, and the vertical axis represents the threshold voltage configuration of string selection cells 1111, 1112, 1113, 1121, 1122, 1123, 1131, 1132, 1133, 1141, 1142, 1143, 1151, 1152, 1153, 1161, 1162, and 1163.

TABLE 5
Relationship Between Control Voltage Configuration
and Threshold Voltage Configuration

| | SSL_111, | | | | | |
|---|---|---|---|---|---|---|
| | SSL_112, | | | | | |
| | SSL_113 | | | | | |
| | V1, | V2, | V2, | V1, | V1, | V3, |
| | V2, | V1, | V2, | V1, | V3, | V1, |
| | V2 | V2 | V1 | V3 | V1 | V1 |
| 1111, 1112, 1113: | ON | OFF | OFF | OFF | OFF | OFF |
| S1, S2, S2 | | | | | | |
| 1121, 1122, 1123: | OFF | ON | OFF | OFF | OFF | OFF |
| S2, S1, S2 | | | | | | |
| 1131, 1132, 1133: | OFF | OFF | ON | OFF | OFF | OFF |
| S2, S2, S1 | | | | | | |
| 1141, 1142, 1143: | OFF | OFF | OFF | ON | OFF | OFF |
| S1, S1, S3 | | | | | | |
| 1151, 1152, 1153: | OFF | OFF | OFF | OFF | ON | OFF |
| S1, S3, S1 | | | | | | |
| 1161, 1162, 1163: | OFF | OFF | OFF | OFF | OFF | ON |
| S3, S1, S1 | | | | | | |

Please refer to Table 5, FIG. 10, and FIG. 11. These string selection cells are adjusted to multiple threshold voltages that differ from each other (e.g., threshold voltages S1, S2, and S3). For example, in the first row, the threshold voltages of the string selection cells 1111, 1112, and 1113 are respectively threshold voltages S1, S2, and S2. In the second row, the threshold voltages of the string selection cells 1121, 1122, and 1123 are respectively threshold voltages S2, S1, and S2. In the third row, the threshold voltages of the string selection cells 1131, 1132, and 1133 are respectively threshold voltages S2, S2, and S1. In the fourth row, the threshold voltages of the string selection cells 1141, 1142, and 1143 are respectively threshold voltages S1, S1, and S3. In the fifth row, the threshold voltages of the string selection cells 1151, 1152, and 1153 are respectively threshold voltages S1, S3, and S1. In the sixth row, the threshold voltages of the string selection cells 1161, 1162, and 1163 are respectively threshold voltages S3, S1, and S1.

In response to the control voltage of string selection line SSL_111 being at voltage level V1 between threshold voltages S1 and S2, the control voltage of string selection line SSL_112 being at voltage level V2 between threshold voltages S2 and S3, and the control voltage of string selection line SSL_113 being at voltage level V2, the string selection cells 1111, 1112, and 1113 of the first row memory cell string are turned on, while at least one of the three string selection cells in each memory cell string of the other rows is turned off. In response to the control voltage of string selection line SSL_111 being at voltage level V2, the control voltage of string selection line SSL_112 being at voltage level V1, and the control voltage of string selection line SSL_113 being at voltage level V2, the string selection cells 1121, 1122, and 1123 of the second row memory cell string are turned on, while at least one of the three string selection cells in each memory cell string of the other rows is turned off. In response to the control voltage of string selection line SSL_111 being at voltage level V2, the control voltage of string selection line SSL_112 being at voltage level V2, and the control voltage of string selection line SSL_113 being at voltage level V1, the string selection cells 1131, 1132, and 1133 of the third row memory cell string are turned on, while at least one of the three string selection cells in each memory cell string of the other rows is turned off. In response to the control voltage of string selection line SSL_111 being at voltage level V1, the control voltage of string selection line SSL_112 being at voltage level V1, and the control voltage of string selection line SSL_113 being at voltage level V3 greater than threshold voltage S3, the string selection cells 1141, 1142, and 1143 of the fourth row memory cell string are turned on, while at least one of the three string selection cells in each memory cell string of the other rows is turned off. In response to the control voltage of string selection line SSL_111 being at voltage level V1, the control voltage of string selection line SSL_112 being at voltage level V3, and the control voltage of string selection line SSL_113 being at voltage level V1, the string selection cells 1151, 1152, and 1153 of the fifth row memory cell string are turned on, while at least one of the three string selection cells in each memory cell string of the other rows is turned off. In response to the control voltage of string selection line SSL_111 being at voltage level V3, the control voltage of string selection line SSL_112 being at voltage level V1, and the control voltage of string selection line SSL_113 being at voltage level V1, the string selection cells 1161, 1162, and 1163 of the sixth row memory cell string are turned on, while at least one of the three string selection cells in each memory cell string of the other rows is turned off.

In summary, the memory cell string array 110 has multiple rows, wherein different rows have different string selection cell threshold voltage configurations. Based on the differences in the threshold voltage configurations of the string selection cells, the control circuit 120 may appropriately set the control voltage configurations of multiple string selection lines to selectively turn on the memory cell string of a designated row and turn off the memory cell strings of the other rows.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A non-volatile memory, comprising:
a memory cell string array, comprising a plurality of memory cell strings, wherein each of the plurality of memory cell strings comprises a plurality of string selection cells and a plurality of memory cells, each of a plurality of string selection lines is coupled to a control terminal of a corresponding one of the plurality of string selection cells in each of the plurality of memory cell strings, each of a plurality of word lines is coupled to a control terminal of a corresponding one of the plurality of memory cells in each of the plurality of memory cell strings, each of a plurality of bit lines is coupled to an upper end of each of the plurality of memory cell strings in a corresponding column of the memory cell string array, a first common source line of a plurality of common source lines is coupled to a lower end of each of the plurality of memory cell strings in a first row of the memory cell string array, the plurality of string selection cells of each of the plurality of memory cell strings in the first row have a first threshold voltage configuration, a second common source line of the plurality of common source lines is coupled to a lower end of each of the plurality of memory cell strings in a second row of the memory cell string array, the plurality of string selection cells of each of the plurality of memory cell strings in the second row have a second threshold voltage configuration, a third common source line of the plurality of common source lines is coupled to a lower end of each of the plurality of memory cell strings in a third row of the memory cell string array, the plurality of string selection cells of each of the plurality of memory cell strings in the third row have a third threshold voltage configuration, a fourth common source line of the plurality of common source lines is coupled to a lower end of each of the plurality of memory cell strings in a fourth row of the memory cell string array, the plurality of string selection cells of each of the plurality of memory cell strings in the fourth row have a fourth threshold voltage configuration, and the first threshold voltage configuration, the second threshold voltage configuration, the third threshold voltage configuration, and the fourth threshold voltage configuration are different from one another; and
a control circuit, coupled to the plurality of string selection lines to control the plurality of string selection cells of the plurality of memory cell strings in the memory cell string array, wherein
in response to the plurality of string selection lines with a control voltage configuration turning on the plurality of string selection cells in each of the plurality of memory cell strings in one of the first row, the second row, the third row, and the fourth row, at least one of the plurality of string selection cells in each of the plurality of memory cell strings in other ones of the first row, the second row, the third row, and the fourth row is turned off.

2. The non-volatile memory according to claim 1, wherein the plurality of string selection cells of each of the plurality of memory cell strings are divided into a plurality of cell groups, the plurality of string selection cells belonging to a same cell group have different threshold voltages, threshold voltage compositions of the plurality of cell groups comprises a first threshold voltage composition and a second threshold voltage composition that are different from each other, the plurality of string selection lines is divided into a plurality of line groups, the plurality of string selection lines belonging to a same line group is coupled to different string selection cells of a same cell group among the plurality of cell groups, and the control voltage configuration of the plurality of line groups comprises a first control voltage configuration and a second control voltage configuration that are different from each other.

3. The non-volatile memory according to claim 2, wherein the first threshold voltage composition is a first threshold voltage and a second threshold voltage that is greater than the first threshold voltage, the second threshold voltage composition is the second threshold voltage and the first threshold voltage, control voltages of the plurality of line groups comprises a first voltage level that is between the first threshold voltage and the second threshold voltage or a second voltage level that is greater than the second threshold voltage, the first control voltage configuration is the first voltage level and the second voltage level, and the second control voltage configuration is the second voltage level and the first voltage level.

4. The non-volatile memory according to claim 3, wherein
the plurality of cell groups of each of the plurality of memory cell strings comprises a first cell group and a second cell group, the threshold voltage compositions of the first cell group and the second cell group in the first row are both the first threshold voltage composition, the threshold voltage compositions of the first cell group and the second cell group in the second row are respectively the second threshold voltage composition and the first threshold voltage composition, the threshold voltage compositions of the first cell group and the second cell group in the third row are both the second threshold voltage composition, and the threshold voltage compositions of the first cell group and the second cell group in the fourth row are respectively the first threshold voltage composition and the second threshold voltage composition;
the plurality of line groups of the plurality of string selection lines comprise a first line group coupled to the first cell group and a second line group coupled to the second cell group;
in response to the control voltage configurations of the first line group and the second line group both being the first control voltage configuration, the first cell group and the second cell group in the first row are turned on, and at least one of the first cell group and the second cell group in other rows is turned off;
in response to the control voltage configurations of the first line group and the second line group respectively being the second control voltage configuration and the first control voltage configuration, the first cell group and the second cell group in the second row are turned on, and at least one of the first cell group and the second cell group in the other rows is turned off;
in response to the control voltage configurations of the first line group and the second line group both being the second control voltage configuration, the first cell group and the second cell group in the third row are turned on, and at least one of the first cell group and the second cell group in the other rows is turned off; and
in response to the control voltage configurations of the first line group and the second line group respectively being the first control voltage configuration and the second control voltage configuration, the first cell group and the second cell group in the fourth row are turned on, and at least one of the first cell group and the second cell group in the other rows is turned off.

5. The non-volatile memory according to claim 3, wherein
a fifth common source line of the plurality of common source lines is coupled to a lower end of each of the plurality of memory cell strings in a fifth row of the memory cell string array, a sixth common source line of the plurality of common source lines is coupled to a lower end of each of the plurality of memory cell strings in a sixth row of the memory cell string array, a seventh common source line of the plurality of common source lines is coupled to a lower end of each of the plurality of memory cell strings in a seventh row of the memory cell string array, and an eighth common source line of the plurality of common source lines is coupled to a lower end of each of the plurality of memory cell strings in an eighth row of the memory cell string array; and
the plurality of cell groups of each of the plurality of memory cell strings comprise a first cell group, a second cell group, and a third cell group, the threshold voltage compositions of the first cell group, the second cell group, and the third cell group in the first row are all the first threshold voltage composition, the threshold voltage compositions of the first cell group, the second cell group, and the third cell group in the second row are respectively the second threshold voltage composition, the first threshold voltage composition, and the first threshold voltage composition, the threshold voltage compositions of the first cell group, the second cell group, and the third cell group in the third row are respectively the second threshold voltage composition, the second threshold voltage composition, and the first threshold voltage composition, the threshold voltage compositions of the first cell group, the second cell group, and the third cell group in the fourth row are respectively the second threshold voltage composition, the first threshold voltage composition, and the second threshold voltage composition, the threshold voltage compositions of the first cell group, the second cell group, and the third cell group in the fifth row are respectively the first threshold voltage composition, the second threshold voltage composition, and the second threshold voltage composition, the threshold voltage compositions of the first cell group, the second cell group, and the third cell group in the sixth row are respectively the first threshold voltage composition, the second threshold voltage composition, and the first threshold voltage composition, the threshold voltage compositions of the first cell group, the second cell group, and the third cell group in the seventh row are respectively the first threshold voltage composition, the first threshold voltage composition, and the second threshold voltage composition, and the threshold voltage compositions of the first cell group, the second cell group, and the third cell group in the eighth row are all the second threshold voltage composition.

6. The non-volatile memory according to claim 5, wherein
the plurality of line groups of the plurality of string selection lines comprise a first line group coupled to the first cell group, a second line group coupled to the second cell group, and a third line group coupled to the third cell group;
in response to the control voltage configurations of the first line group, the second line group, and the third line group all being the first control voltage configuration, the first cell group, the second cell group, and the third cell group in the first row are turned on, and at least one of the first cell group, the second cell group, and the third cell group in other rows is turned off;
in response to the control voltage configurations of the first line group, the second line group, and the third line group respectively being the second control voltage configuration, the first control voltage configuration, and the first control voltage configuration, the first cell group, the second cell group, and the third cell group in the second row are turned on, and at least one of the first cell group, the second cell group, and the third cell group in the other rows is turned off;
in response to the control voltage configurations of the first line group, the second line group, and the third line group respectively being the second control voltage configuration, the second control voltage configuration, and the first control voltage configuration, the first cell group, the second cell group, and the third cell group in the third row are turned on, and at least one of the first cell group, the second cell group, and the third cell group in the other rows is turned off;
in response to the control voltage configurations of the first line group, the second line group, and the third line group respectively being the second control voltage configuration, the first control voltage configuration, and the second control voltage configuration, the first cell group, the second cell group, and the third cell group in the fourth row are turned on, and at least one of the first cell group, the second cell group, and the third cell group in the other rows is turned off;
in response to the control voltage configurations of the first line group, the second line group, and the third line group respectively being the first control voltage configuration, the second control voltage configuration, and the second control voltage configuration, the first cell group, the second cell group, and the third cell group in the fifth row are turned on, and at least one of the first cell group, the second cell group, and the third cell group in the other rows is turned off;
in response to the control voltage configurations of the first line group, the second line group, and the third line group respectively being the first control voltage configuration, the second control voltage configuration, and the first control voltage configuration, the first cell group, the second cell group, and the third cell group in the sixth row are turned on, and at least one of the first cell group, the second cell group, and the third cell group in the other rows is turned off;
in response to the control voltage configurations of the first line group, the second line group, and the third line group respectively being the first control voltage configuration, the first control voltage configuration, and the second control voltage configuration, the first cell group, the second cell group, and the third cell group in the seventh row are turned on, and at least one of the first cell group, the second cell group, and the third cell group in the other rows is turned off; and
in response to the control voltage configurations of the first line group, the second line group, and the third line group all being the second control voltage configuration, the first cell group, the second cell group, and the third cell group in the eighth row are turned on, and at least one of the first cell group, the second cell group, and the third cell group in the other rows is turned off.

7. The non-volatile memory according to claim 1, wherein one of the plurality of string selection cells in each of the plurality of memory cell strings is configured at a first threshold voltage, and other ones of the plurality of string selection cells in each of the plurality of memory cell strings are configured at a second threshold voltage that is greater than the first threshold voltage, a position of the string selection cell configured at the first threshold voltage in the memory cell string of the first row is different from a position of the string selection cell configured at the first threshold voltage in the memory cell string of the second row, the position of the string selection cell configured at the first threshold voltage in the memory cell string of the second row is different from a position of the string selection cell configured at the first threshold voltage in the memory cell string of the third row, and the position of the string selection cell configured at the first threshold voltage in the memory cell string of the third row is different from a position of the string selection cell configured at the first threshold voltage in the memory cell string of the fourth row.

8. The non-volatile memory according to claim 7, wherein
the plurality of string selection lines comprise a first string selection line coupled to a first string selection cell of the plurality of string selection cells in each of the plurality of memory cell strings, a second string selection line coupled to a second string selection cell of the plurality of string selection cells in each of the plurality of memory cell strings, a third string selection line coupled to a third string selection cell of the plurality of string selection cells in each of the plurality of memory cell strings, and a fourth string selection line coupled to a fourth string selection cell of the plurality of string selection cells in each of the plurality of memory cell strings; and
the first string selection cell in the memory cell string of the first row is configured at the first threshold voltage, the second string selection cell in the memory cell string of the second row is configured at the first threshold voltage, the third string selection cell in the memory cell string of the third row is configured at the first threshold voltage, and the fourth string selection cell in the memory cell string of the fourth row is configured at the first threshold voltage.

9. The non-volatile memory according to claim 8, wherein
in response to a control voltage of the first string selection line being a first voltage level between the first threshold voltage and the second threshold voltage, and a control voltage of other string selection lines being a second voltage level greater than the second threshold voltage, the plurality of string selection cells in each of the plurality of memory cell strings of the first row are turned on, and at least one of the plurality of string selection cells in each of the plurality of memory cell strings in other rows is turned off;
in response to a control voltage of the second string selection line being the first voltage level, and the control voltage of the other string selection lines being the second voltage level, the plurality of string selection cells in each of the plurality of memory cell strings of the second row are turned on, and the at least one of the plurality of string selection cells in each of the plurality of memory cell strings in the other rows is turned off;
in response to a control voltage of the third string selection line being the first voltage level, and the control voltage of the other string selection lines being the second voltage level, the plurality of string selection cells in each of the plurality of memory cell strings of the third row are turned on, and the at least one of the plurality of string selection cells in each of the plurality of memory cell strings in the other rows is turned off; and
in response to a control voltage of the fourth string selection line being the first voltage level, and the control voltage of the other string selection lines being the second voltage level, the plurality of string selection cells in each of the plurality of memory cell strings of the fourth row are turned on, and the at least one of the plurality of string selection cells in each of the plurality of memory cell strings in the other rows is turned off.

10. The non-volatile memory according to claim 1, wherein the plurality of string selection cells are trimmed to a plurality of threshold voltages different from one another, the plurality of threshold voltages are divided into a plurality of threshold voltage pairs, an upper threshold voltage and a lower threshold voltage of a first threshold voltage pair of the plurality of threshold voltage pairs are both between an upper threshold voltage and a lower threshold voltage of a second threshold voltage pair of the plurality of threshold voltage pairs, and the plurality of string selection cells in each of the plurality of memory cell strings in a same row are trimmed to different threshold voltages of a same corresponding one of the plurality of threshold voltage pairs.

11. The non-volatile memory according to claim 10, wherein the plurality of threshold voltages of the plurality of string selection cells comprise a first threshold voltage, a second threshold voltage, a third threshold voltage, and a fourth threshold voltage, the second threshold voltage and the third threshold voltage are the lower threshold voltage and the upper threshold voltage of the first threshold voltage pair, the first threshold voltage and the fourth threshold voltage are the lower threshold voltage and the upper threshold voltage of the second threshold voltage pair, each of the plurality of memory cell strings comprises a first string selection cell and a second string selection cell, a threshold voltage of the first string selection cell and a threshold voltage of the second string selection cell in the plurality of memory cell strings of the first row are respectively the fourth threshold voltage and the first threshold voltage, the threshold voltage of the first string selection cell and the threshold voltage of the second string selection cell in the plurality of memory cell strings of the second row are respectively the second threshold voltage and the third threshold voltage, the threshold voltage of the first string selection cell and the threshold voltage of the second string selection cell in the plurality of memory cell strings of the third row are respectively the third threshold voltage and the second threshold voltage, and the threshold voltage of the first string selection cell and the threshold voltage of the second string selection cell in the plurality of memory cell strings of the fourth row are respectively the first threshold voltage and the fourth threshold voltage.

12. The non-volatile memory according to claim 11, wherein
the plurality of string selection lines comprise a first string selection line coupled to the first string selection cell of the plurality of memory cell strings and a second string selection line coupled to the second string selection cell of the plurality of memory cell strings;
in response to a control voltage of the first string selection line being a fourth voltage level greater than the fourth threshold voltage and a control voltage of the second string selection line being a first voltage level between the first threshold voltage and the second threshold voltage, the first string selection cell and the second string selection cell in the plurality of memory cell strings of the first row are turned on, and at least one of the first string selection cell and the second string selection cell in the plurality of memory cell strings in other rows is turned off;
in response to the control voltage of the first string selection line being a second voltage level between the second threshold voltage and the third threshold voltage and the control voltage of the second string selection line being a third voltage level between the third threshold voltage and the fourth voltage level, the first string selection cell and the second string selection cell in the plurality of memory cell strings of the second row are turned on, and the at least one of the first string selection cell and the second string selection cell in the plurality of memory cell strings in the other rows is turned off;
in response to the control voltage of the first string selection line being the third voltage level and the control voltage of the second string selection line being the second voltage level, the first string selection cell and the second string selection cell in the plurality of memory cell strings of the third row are turned on, and the at least one of the first string selection cell and the second string selection cell in the plurality of memory cell strings in the other rows is turned off; and
in response to the control voltage of the first string selection line being the first voltage level and the control voltage of the second string selection line being the fourth voltage level, the first string selection cell and the second string selection cell in the plurality of memory cell strings of the fourth row are turned on, and the at least one of the first string selection cell and the second string selection cell in the plurality of memory cell strings in the other rows is turned off.

13. The non-volatile memory according to claim 10, wherein
a fifth common source line of the plurality of common source lines is coupled to a lower end of each of the plurality of memory cell strings in a fifth row of the memory cell string array, and a sixth common source line of the plurality of common source lines is coupled to a lower end of each of the plurality of memory cell strings in a sixth row of the memory cell string array;
the plurality of threshold voltages of the plurality of string selection cells comprise a first threshold voltage, a second threshold voltage, a third threshold voltage, a fourth threshold voltage, a fifth threshold voltage, and a sixth threshold voltage, the third threshold voltage and the fourth threshold voltage are respectively the lower threshold voltage and the upper threshold voltage of the first threshold voltage pair, the second threshold voltage and the fifth threshold voltage are respectively the lower threshold voltage and the upper threshold voltage of the second threshold voltage pair, the first threshold voltage and the sixth threshold voltage are respectively a lower threshold voltage and an upper threshold voltage of a third threshold voltage pair of the plurality of threshold voltage pairs, and the upper threshold voltage and the lower threshold voltage of the second threshold voltage pair are both between the upper threshold voltage and the lower threshold voltage of the third threshold voltage pair; and
the plurality of string selection cells of each of the plurality of memory cell strings comprise a first string selection cell and a second string selection cell, a threshold voltage of the first string selection cell and a threshold voltage of the second string selection cell in the plurality of memory cell strings of the first row are respectively the sixth threshold voltage and the first threshold voltage, the threshold voltage of the first string selection cell and the threshold voltage of the second string selection cell in the plurality of memory cell strings of the second row are respectively the fifth threshold voltage and the second threshold voltage, the threshold voltage of the first string selection cell and the threshold voltage of the second string selection cell in the plurality of memory cell strings of the third row are respectively the fourth threshold voltage and the third threshold voltage, the threshold voltage of the first string selection cell and the threshold voltage of the second string selection cell in the plurality of memory cell strings of the fourth row are respectively the third threshold voltage and the fourth threshold voltage, the threshold voltage of the first string selection cell and the threshold voltage of the second string selection cell in the plurality of memory cell strings of the fifth row are respectively the second threshold voltage and the fifth threshold voltage, and the threshold voltage of the first string selection cell and the threshold voltage of the second string selection cell in the plurality of memory cell strings of the sixth row are respectively the first threshold voltage and the sixth threshold voltage.

14. The non-volatile memory according to claim 13, wherein
the plurality of string selection lines comprise a first string selection line coupled to the first string selection cell of the plurality of memory cell strings and a second string selection line coupled to the second string selection cell of the plurality of memory cell strings;
in response to a control voltage of the first string selection line being a sixth voltage level greater than the sixth threshold voltage and a control voltage of the second string selection line being a first voltage level between the first threshold voltage and the second threshold voltage, the first string selection cell and the second string selection cell in the plurality of memory cell strings of the first row are turned on, and at least one of the first string selection cell and the second string selection cell in the plurality of memory cell strings in other rows is turned off;
in response to the control voltage of the first string selection line being a fifth voltage level between the fifth threshold voltage and the sixth threshold voltage and the control voltage of the second string selection line being a second voltage level between the second threshold voltage and the third threshold voltage, the first string selection cell and the second string selection cell in the plurality of memory cell strings of the second row are turned on, and the at least one of the first string selection cell and the second string selection cell in the plurality of memory cell strings in the other rows is turned off;
in response to the control voltage of the first string selection line being a fourth voltage level between the fourth threshold voltage and the fifth threshold voltage and the control voltage of the second string selection line being a third voltage level between the third threshold voltage and the fourth threshold voltage, the first string selection cell and the second string selection cell in the plurality of memory cell strings of the third row are turned on, and the at least one of the first string selection cell and the second string selection cell in the plurality of memory cell strings in the other rows is turned off;
in response to the control voltage of the first string selection line being the third voltage level and the control voltage of the second string selection line being the fourth voltage level, the first string selection cell and the second string selection cell in the plurality of memory cell strings of the fourth row are turned on, and the at least one of the first string selection cell and the second string selection cell in the plurality of memory cell strings in the other rows is turned off;
in response to the control voltage of the first string selection line being the second voltage level and the control voltage of the second string selection line being the fifth voltage level, the first string selection cell and the second string selection cell in the plurality of memory cell strings of the fifth row are turned on, and the at least one of the first string selection cell and the second string selection cell in the plurality of memory cell strings in the other rows is turned off; and
in response to the control voltage of the first string selection line being the sixth voltage level and the control voltage of the second string selection line being the first voltage level, the first string selection cell and the second string selection cell in the plurality of memory cell strings of the sixth row are turned on, and the at least one of the first string selection cell and the second string selection cell in the plurality of memory cell strings in the other rows is turned off.

15. The non-volatile memory according to claim 1, wherein
a plurality of threshold voltages of the plurality of string selection cells comprise a first threshold voltage, a second threshold voltage, and a third threshold voltage;
the plurality of string selection cells of each of the plurality of memory cell strings comprise a first string selection cell, a second string selection cell, and a third string selection cell;
a fifth common source line of the plurality of common source lines is coupled to a lower end of each of the plurality of memory cell strings in a fifth row of the memory cell string array, and a sixth common source line of the plurality of common source lines is coupled to a lower end of each of the plurality of memory cell strings in a sixth row of the memory cell string array; and
the plurality of threshold voltages of the first string selection cell, the second string selection cell, and the third string selection cell in the plurality of memory cell strings of the first row are respectively the first threshold voltage, the second threshold voltage, and the second threshold voltage, the plurality of threshold voltages of the first string selection cell, the second string selection cell, and the third string selection cell in the plurality of memory cell strings of the second row are respectively the second threshold voltage, the first threshold voltage, and the second threshold voltage, the plurality of threshold voltages of the first string selection cell, the second string selection cell, and the third string selection cell in the plurality of memory cell strings of the third row are respectively the second threshold voltage, the second threshold voltage, and the first threshold voltage, the plurality of threshold voltages of the first string selection cell, the second string selection cell, and the third string selection cell in the plurality of memory cell strings of the fourth row are respectively the first threshold voltage, the first threshold voltage, and the third threshold voltage, the plurality of threshold voltages of the first string selection cell, the second string selection cell, and the third string selection cell in the plurality of memory cell strings of the fifth row are respectively the first threshold voltage, the third threshold voltage, and the first threshold voltage, and the plurality of threshold voltages of the first string selection cell, the second string selection cell, and the third string selection cell in the plurality of memory cell strings of the sixth row are respectively the third threshold voltage, the first threshold voltage, and the first threshold voltage.

16. The non-volatile memory according to claim 15, wherein
the plurality of string selection lines comprise a first string selection line coupled to the first string selection cell of the plurality of memory cell strings, a second string selection line coupled to the second string selection cell of the plurality of memory cell strings, and a third string selection line coupled to the third string selection cell of the plurality of memory cell strings;
in response to a control voltage of the first string selection line being a first voltage level between the first threshold voltage and the second threshold voltage, a control voltage of the second string selection line being a second voltage level between the second threshold voltage and the third threshold voltage, and a control voltage of the third string selection line being the second voltage level, the first string selection cell, the second string selection cell, and the third string selection cell in the plurality of memory cell strings of the first row are turned on, and at least one of the first string selection cell, the second string selection cell, and the third string selection cell in the plurality of memory cell strings in other rows is turned off;
in response to the control voltage of the first string selection line being the second voltage level, the control voltage of the second string selection line being the first voltage level, and the control voltage of the third string selection line being the second voltage level, the first string selection cell, the second string selection cell, and the third string selection cell in the plurality of memory cell strings of the second row are turned on, and the at least one of the first string selection cell, the second string selection cell, and the third string selection cell in the plurality of memory cell strings in the other rows is turned off;
in response to the control voltage of the first string selection line being the second voltage level, the control voltage of the second string selection line being the second voltage level, and the control voltage of the third string selection line being the first voltage level, the first string selection cell, the second string selection cell, and the third string selection cell in the plurality of memory cell strings of the third row are turned on, and the at least one of the first string selection cell, the second string selection cell, and the third string selection cell in the plurality of memory cell strings in the other rows is turned off;
in response to the control voltage of the first string selection line being the first voltage level, the control voltage of the second string selection line being the first voltage level, and the control voltage of the third string selection line being a third voltage level greater than the third threshold voltage, the first string selection cell, the second string selection cell, and the third string selection cell in the plurality of memory cell strings of the fourth row are turned on, and the at least one of the first string selection cell, the second string selection cell, and the third string selection cell in the plurality of memory cell strings in the other rows is turned off;
in response to the control voltage of the first string selection line being the first voltage level, the control voltage of the second string selection line being the third voltage level, and the control voltage of the third string selection line being the first voltage level, the first string selection cell, the second string selection cell, and the third string selection cell in the plurality of memory cell strings of the fifth row are turned on, and the at least one of the first string selection cell, the second string selection cell, and the third string selection cell in the plurality of memory cell strings in the other rows is turned off; and
in response to the control voltage of the first string selection line being the third voltage level, the control voltage of the second string selection line being the first voltage level, and the control voltage of the third string selection line being the first voltage level, the first string selection cell, the second string selection cell, and the third string selection cell in the plurality of memory cell strings of the sixth row are turned on, and the at least one of the first string selection cell, the second string selection cell, and the third string selection cell in the plurality of memory cell strings in the other rows is turned off.
